(19) United States
(12) Patent Application Publication
(10) Pub. No.: US 2015/0097564 A1
(43) Pub. Date: Apr. 9, 2015

(54) Device Having at Least One Channel and at Least Two Liquids

(71) Applicant: Bernd Maciejewski, Markt Erlbach (DE)

(72) Inventor: Bernd Maciejewski, Markt Erlbach (DE)

(21) Appl. No.: 14/504,613

(22) Filed: Oct. 2, 2014

(30) Foreign Application Priority Data
Oct. 8, 2013 (DE) 102013220282.2

(51) Int. Cl. G01R 33/28; G01R 33/385; G01R 33/30

(52) U.S. Cl. CPC G01R 33/283; G01R 33/307; G01R 33/385
USPC 324/318

(57) ABSTRACT

The embodiments relate to devices having at least one channel and at least two liquids, to a housing element and to a medical imaging apparatus. In order for the device to achieve a design effect by liquids, it is proposed that the device includes at least one channel, wherein the at least one channel has at least one first liquid including a first density and at least one second liquid including a second density, wherein the first density is different from the second density, wherein the at least one first liquid and the at least one second liquid are arranged at least partially inside the at least one channel and the at least one first liquid has a plurality of structures that are demarcated from the at least one second liquid and which, when acted upon by a force, execute a movement inside the at least one channel.

### CROSS-REFERENCE TO RELATED APPLICATIONS

This application claims the benefit of DE 10 2013 220 282.2, filed on Oct. 10, 2013, which is hereby incorporated by reference in its entirety.

### TECHNICAL FIELD

The embodiments relate to devices having at least one channel and at least two liquids, to a housing element, and to a medical imaging apparatus.

### BACKGROUND

In medical imaging apparatuses, (e.g., magnetic resonance apparatuses), increasing attention is being focused on the design of the housings of the medical imaging apparatuses in order to increase the optical attractiveness of the medical imaging apparatuses. Light effects are frequently employed as design effects in this regard.

### SUMMARY AND DESCRIPTION

The scope of the present invention is defined solely by the appended claims and is not affected to any degree by the statements within this summary. The present embodiments may obviate one or more of the drawbacks or limitations in the related art.

The embodiments relate to devices that have at least one channel, wherein the at least one channel has at least one first liquid having a first density and at least one second liquid having a second density. The first density is different from the second density. The at least one first liquid and the at least one second liquid are arranged at least partially inside the at least one channel. The at least one first liquid has a plurality of structures that are demarcated from the at least one second liquid and which, when acted upon by a force, execute a movement inside the at least one channel.

The at least one first liquid and the at least one second liquid may not mix with one another and/or may be present largely separated from one another. Toward that end, the at least one first liquid may form a first phase and the at least one second liquid may form a second phase, the first phase and the second phase being present separately from one another. The at least one first liquid and the at least one second liquid may have different polarities. As a result, the at least one first liquid and the at least one second liquid may mutually repel one another, thereby preventing the at least one first liquid and the at least one second liquid from intermixing. The at least one first liquid and the at least one second liquid may be present together in the at least one channel. For this purpose, the at least one channel may include the at least one first liquid and the at least one second liquid.

At least one separating layer may form between the at least one first liquid and the at least one second liquid such that the at least one first liquid has a plurality of structures demarcated from the at least one second liquid. At least one of the demarcated structures is of such a size that the at least one demarcated structure is visible to an observer of the demarcated structure. The size may be, for example, at least 1 mm, at least 5 mm, or at least 10 mm. The demarcated structures have a spherical and/or globular shape.

The ability of the demarcated structures of the at least one first liquid to execute a movement inside the at least one channel provides that the demarcated structures stream and/or flow through the at least one channel. This may happen as a result of the action of an external force, such as the force of gravity, or possibly also of a pumping force generated by a pump and/or of a compressive force. The at least one second liquid may be present as stationary in the at least one channel and/or at least partially fill the at least one channel. The at least one first liquid may flow through and/or be conducted through the at least one second liquid.

The at least one first liquid and the at least one second liquid may be different from one another in at least one visible feature. The at least one first liquid may be water, possibly containing substances dissolved in water, such as pigments. The at least one second liquid may be oil, for example, transparent oil and/or white oil.

The device has a design effect, that is to say possesses an optical attractiveness for an observer. The device may therefore be used as a design element for another device, e.g., a housing. The at least two liquids of the device, of which the at least one first liquid moves through the at least one channel, may result in a special design effect of the device, since the moving at least one first liquid creates a special dynamic for an observer of the device. In this case, the at least one channel may be embodied and/or shaped in accordance with design considerations. The fact that the at least one first liquid is present in the form of demarcated structures, in particular, in globular and/or spherical form, in the at least one channel may lead to a reinforcement of the design effect and may allow a clear optical demarcation of the at least one first liquid from the at least one second liquid. This may also result in a calming effect for an observer, since the latter may follow the demarcated structures in their movement through the at least one channel with the observer's eyes.

One embodiment variant provides that the at least one first liquid and the at least one second liquid have different colors. The at least one first liquid may be colored and the at least one second liquid colorless, in particular, optically clear. If the at least one channel includes a plurality of first liquids, the plurality of first liquids may be of different colors. The different colors of the at least one first and at least one second liquid make the liquids particularly optically distinguishable from one another and consequently enhance the design effect of the device.

One embodiment variant provides that the at least one first liquid has a higher density than the at least one second liquid. The at least one first liquid, in particular, the demarcated structures of the at least one first liquid, may flow and/or be conducted through the at least one channel in the direction of the force of gravity. For this purpose, there is no need for pumping power, for example, and/or other externally acting force. Alternatively, the at least one first liquid may have a lower density than the at least one second liquid. In that case, the at least one first liquid may ascend through the at least one channel in the opposite direction to the force of gravity.

One embodiment variant provides that the device has a plurality of channels that are embodied in such a way that the demarcated structures of the at least one first liquid, when acted upon by the force, simultaneously execute a movement through the plurality of channels. The plurality of channels may be arranged adjacent to one another, in particular largely parallel to one another. The simultaneous movement of the demarcated structures of the at least one first liquid through the plurality of channels may provide that a plurality of demarcated structures are present and in each case some of the plurality of demarcated structures move through one of the plurality of channels in each case. The use of a plurality of channels in turn enhances the design effect of the device. For this purpose, the plurality of channels may be coordinated with one another in accordance with design considerations and/or be arranged as complementary to one another.

One embodiment variant provides that the device has at least one first shell having at least one first recess and a second shell having at least one second recess, wherein the at least one first recess corresponds to the at least one second recess in such a way that when the at least one first shell is joined to the at least one second shell the at least one first recess forms the at least one channel together with the at least one second recess. In this case, the at least one shell, in particular the shell pointing toward an observer of the device in an application case of the device, is embodied as optically transparent so that it is possible to observe the liquids in the at least one channel from outside. The at least one first shell and the at least one second shell may have one or more indentations that are coordinated with one another in such a way that they form a channel in each case when the two shells are joined together. The indentations may be incorporated into the at least one first shell and/or into the at least one second shell by milling. In this case, the two shells may be joined together by an adhesive layer. Alternatively, the device may also be produced in a single part in a twin-sheet thermoforming process with the at least one channel being formed by extrusion during the manufacture of the device. Producing the device, in particular the channels of the device, by the twin-sheet thermoforming process may result in a perfect sealing of the channels. The device also includes at least one third shell that serves as a cover and compensates for possible irregularities at the surface of the device due to the twin-sheet thermoforming production process.

One embodiment variant provides that the device has at least one nozzle that is embodied in such a way as to introduce the at least one first liquid in the form of demarcated structures into the at least one channel. After being introduced into the at least one channel in the form of, in particular largely globule-shaped and/or spherical, demarcated structures, the at least one first liquid may move through the channel and/or flow inside the channel. Each channel may include one nozzle. The at least one nozzle may be mounted at the point at which the at least one first liquid is introduced into the channel. The nozzle may have an orifice through which the at least one first liquid may be conducted. In this arrangement, the orifice of the at least one nozzle may be embodied as tapered on the side facing toward the at least one channel. The at least one nozzle may be embodied as passive, such that the at least one first liquid is conducted through the at least one nozzle solely by its weight force and/or as a result of an external pumping power. In particular, the at least one first liquid will collect at the nozzle until the weight force of the at least one first liquid induces the at least one first liquid to flow and/or be introduced in the form of demarcated structures into the at least one channel through the at least one nozzle. Alternatively, the nozzle may also be embodied electrically and be in particular a dispenser. The nozzle may be embodied to introduce the at least one first liquid actively into the at least one channel. For this purpose, the nozzle may be externally controllable, for example, by a piezoelectric element. In this case, the at least one nozzle may offer a possibility of introducing the at least one first liquid in the form of demarcated structures into the at least one channel.

One embodiment variant provides that the device has at least one pump that is embodied to set the at least one first liquid in motion. In this case, the pump may exert a pumping action and/or a pumping force that moves the at least one first liquid away from the position of the pump. The pump may also exert a suction effect that moves the at least one first liquid toward the pump. The pump may be embodied such that its pumping capacity is tuned to the flow velocity of the at least one first liquid in the at least one channel. In order to enhance the design effect of the device, the pump may also have a variable pumping capacity so that the flow velocity of the at least one first liquid may be varied.

One embodiment variant provides that the device has at least one first end section and at least one second end section that is positioned opposite the at least one first end section, and that the device has at least one first reservoir and at least one second reservoir. The at least one first reservoir is arranged in the at least first end section and the at least one second reservoir is arranged in the at least one second end section, the first reservoir being connected to the at least one second reservoir by way of the at least one channel. The two reservoirs may be positioned at opposite positions of the devices. In particular, the at least one channel is embodied to conduct the at least one first liquid from the first reservoir into the second reservoir and/or from the second reservoir into the first reservoir. Toward that end, with regard to a positioning direction of the device in the application case, the first reservoir may be positioned above the second reservoir in accordance with the force of gravity direction. The at least one first liquid may collect in the first reservoir until it is introduced as a result of its weight force and/or a positive pressure, in particular through the nozzles of the channels, into the at least one channel. The at least one first liquid may be conducted through the at least one channel and collect again in the second reservoir.

One embodiment variant provides that the at least one pump is embodied so as to pump the at least one first liquid out of the at least one second reservoir into the at least one first reservoir. The at least one pump may close the circuit of the at least one first liquid. If the at least one first liquid has a higher density than the at least one second liquid, the pump may pump the at least one first liquid in the opposite direction to the force of gravity. If the at least one first liquid has a lower density than the at least one second liquid, the pump may pump and/or suck the at least one first liquid in the direction of the force of gravity.

One embodiment variant provides that the device has at least one feed channel that is embodied differently from the at least one channel, the at least one first reservoir being connected to the at least one second reservoir by way of the at least one feed channel. The feed channel may be embodied to conduct the at least one first liquid back into the first reservoir again after the liquid has moved through the at least one channel from the first reservoir into the second reservoir. In particular, the feed channel may be positioned in such a way that the feed channel is hidden from an observer of the device, e.g., by a housing element and/or a part of the device. The feed channel may be connected to the pump so that the at least one first liquid is pumped between the reservoirs through the feed channel. The at least one pump may be embodied so as to pump the at least one first liquid out of the at least one second reservoir into the at least one first reservoir by way of the at least one feed channel.

One embodiment variant provides that the device has at least one light source, the at least one light source being embodied in such a way that the light source enables the device to be illuminated. The device includes two light sources, one of which is positioned in the first end section, and the other of which is positioned in the second end section of the device. The light sources and the illumination of the device generated by the light sources may lead to an enhancement of the design effect of the device.

One embodiment variant provides that the at least one channel is embodied as a light conductor for the light generated by the at least one light source. This may lead to a homogeneous illumination of the device, in particular of the at least one first liquid in the at least one channel. The design effect of the device is enhanced yet again as a result.

One embodiment variant provides that the device is embodied as magnetic resonance compatible. This is particularly beneficial when the device is intended to be used as a design element for a medical imaging apparatus, in particular a magnetic resonance apparatus. The device may be embodied as magnetic resonance compatible such that the device includes for the most part or almost entirely of non-magnetic materials. Thus, for example, the pump of the device may include at least in part of stainless steel. By the use of non-magnetic materials the influencing of the magnetic fields or radiofrequency waves in the magnetic resonance apparatus may be reduced or precluded. Using non-magnetic materials may also prevent artifacts being produced on the images acquired by the magnetic resonance apparatus. Components of the device that are critical with regard to magnetic resonance compatibility, (e.g., the pump), are positioned outside of a magnetic field generated by the magnetic resonance apparatus and/or are screened off from the generated magnetic field. This leads to the result that the magnetic field does not disrupt the functioning of the critical components and/or the critical components do not disrupt the magnetic field.

The housing element includes the device. In this case, the housing element may be a part of a housing of an apparatus, in particular a medical imaging apparatus. The device is arranged on the housing element. The part of the device arranged on the outside of the housing element is optically effective and/or has a design effect, such as the at least one channel of the device having the at least one first liquid and the at least one second liquid, for example. The housing element may be embodied as optically transparent in one area of the device. The housing element may be located in an indentation in the housing in which the device is installed. The housing element has an optical design effect by the device. In this way, the housing element together with the device may increase the optical attractiveness of the housing belonging to the housing element.

One embodiment variant provides that the device is embodied in a curved shape, the curvature of the device being configured to match a curvature of the shape of the housing element. In particular, the at least one channel of the device is matched to the curvature of the shape of the housing element. This may provide that the at least one channel has a radius of curvature that is matched to a curvature of the shape of the housing element. If the device includes a plurality of channels arranged adjacent to one another, it is beneficial that the plurality of channels have different radii of curvature matched to one another. The curved embodiment of the device, in particular of the channels of the device, may lead to an enhancement of the design effect of the device. Furthermore, the curved embodiment of the device may allow an optimal matching of the device to the shape of the housing element and thus enable an optimal use of the available space.

One embodiment variant provides that the housing element has an optically transparent subsection, the device being at least partially arranged on the optically transparent subsection. The optically transparent subsection of the housing element may be embodied as a recess, with at least a part of the device being arranged and/or integrated and/or mounted in the recess. The recess of the housing element may be arranged on the outside of the housing element, in particular on a housing covering element of the housing element. The optically effective components of the device, in particular the at least one channel, may be arranged on the outside of the housing element in the recess. In this case, the housing element may have a recess and/or indentation for at least one channel of the device. If the device has a plurality of channels, the plurality of channels may be arranged within the recesses of the housing element. The recess has a mounting for the at least one channel. The optically transparent embodiment of a subsection of the housing element offers a particularly space-saving and optically effective possibility for arranging the device on the housing element.

The medical imaging apparatus includes the housing element. The medical imaging apparatus may be in particular a magnetic resonance apparatus. The medical imaging apparatus may also be a computed tomography scanner, an X-ray machine, or a molecular medical imaging apparatus, (e.g., a positron emission tomography system). The medical imaging apparatus may also be a combined medical imaging apparatus having more than one imaging modality, for example, a combined magnetic resonance/positron emission tomography apparatus. The housing element may be arranged on the housing, in particular the outside of the housing, of the medical imaging apparatus. The medical imaging apparatus having the housing element with the device may have a design effect. Toward that end the device is positioned at an optically effective point of the medical imaging apparatus. The device may increase the optical attractiveness of the medical imaging apparatus. The device may also serve as an eye-catcher for the medical imaging apparatus and at trade fairs, for example, draw the attention of trade fair visitors to the medical imaging apparatus. For an observing patient, the device may furthermore help in calming and/or distracting the patient prior to the examination of the patient in the medical imaging apparatus. In particular, when the medical imaging apparatus is employed in a children's hospital, the device may assist in calming the observing child by virtue of the moving at least one first liquid.

One embodiment variant provides that the medical imaging apparatus has a front section, the device being arranged on the front section. The front section, which in particular includes a front covering panel, may be the part of the housing of the medical imaging apparatus that is arranged at the front of the medical imaging apparatus. The front may be the side of the medical imaging apparatus from which a patient is positioned for introduction into the medical imaging apparatus. The device may be integrated into the front section and/or mounted on the front section. The device may be arranged in particular on a side part of the front section. The front section may represent the optically most effective position of the medical imaging apparatus. The device may therefore exhibit its design effect at the front section of the medical imaging apparatus.

### BRIEF DESCRIPTION OF THE DRAWINGS

FIG. 1 depicts an embodiment of a medical imaging apparatus (e.g., magnetic resonance apparatus) in a schematic representation.

FIG. 2 depicts a schematic view of an embodiment of a front section of a medical imaging apparatus including a housing element.

FIG. 3 depicts a schematic side view of an embodiment of a device.

FIG. 4 depicts a schematic view of an embodiment of a first end section of a device, wherein the first end section has a first reservoir of the device and a part of channels of the device.

### DETAILED DESCRIPTION

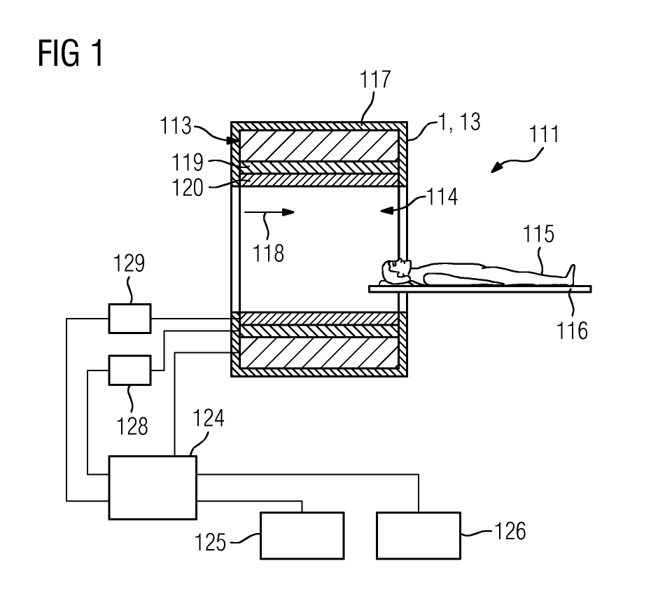

FIG. 1 schematically depicts a medical imaging device that is formed by a magnetic resonance apparatus 111. Furthermore, the medical imaging device may also be formed by a different type of medical imaging device, such as by a magnetic resonance/positron emission tomography device or a computed tomography system, for example.

The magnetic resonance apparatus 111 includes a detector unit formed by a magnet unit 113 and having a main magnet 117 for generating a strong and in particular constant main magnetic field 118. The magnetic resonance apparatus 111 additionally has a cylinder-shaped patient receiving zone 114 for receiving a patient 115, the patient receiving zone 114 being cylindrically enclosed by the magnet unit 113 in a circumferential direction. The patient 115 may be introduced into the patient receiving zone 114 by a patient positioning device 116 of the magnetic resonance apparatus 111. For this purpose, the patient positioning device 116 has a patient table that is movably arranged inside the magnetic resonance apparatus 111.

The magnet unit 113 additionally has a gradient coil unit 119 for generating magnetic field gradients that are used for spatial encoding during an imaging session. The gradient coil unit 119 is controlled by a gradient control unit 128. Furthermore, the magnet unit 113 has a radiofrequency antenna unit 120, which in the case depicted is embodied as a whole-body coil permanently integrated into the magnetic resonance apparatus 111, and a radiofrequency antenna control unit 129 for exciting a polarization that becomes established in the main magnetic field 118 generated by the main magnet 117. The radiofrequency antenna unit 120 is controlled by the radiofrequency antenna control unit 129 and beams high-frequency radiofrequency pulses into an examination space that is substantially formed by the patient receiving zone 114.

In order to control the main magnet 117, the gradient control unit 128, and the radiofrequency antenna control unit 129, the magnetic resonance apparatus 111 has a control unit 124. The control unit 124 centrally controls the magnetic resonance apparatus 111, such as in order to execute magnetic resonance sequences, for example. Control information such as imaging parameters, for example, as well as reconstructed magnetic resonance images may be displayed on a display unit 125, (e.g., on at least one monitor), of the magnetic resonance apparatus 111 for an operator. The magnetic resonance apparatus 111 also has an input unit 126 by which information and/or imaging parameters may be input by an operator during a measurement procedure.

The illustrated magnetic resonance apparatus 111 may include further components that magnetic resonance apparatuses 111 ordinarily have. The general mode of operation of a magnetic resonance apparatus 111 is furthermore known to the person skilled in the art, so a detailed description of the further components will be dispensed with.

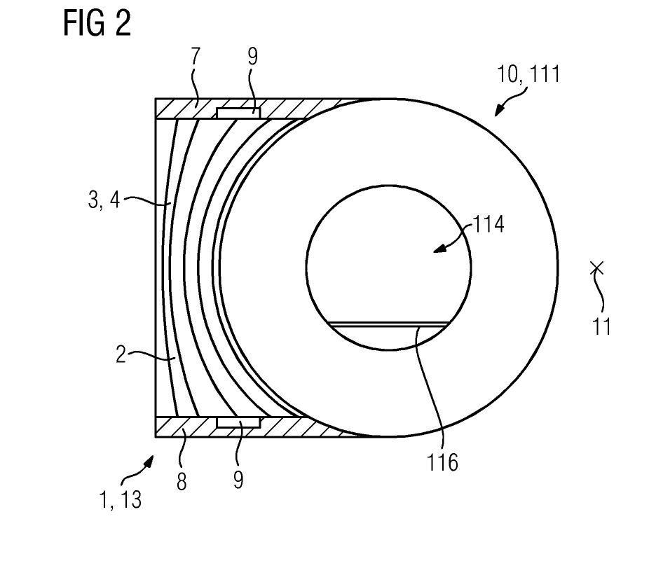

The magnetic resonance apparatus 111 has a housing element 13, the housing element 13 being arranged on the front section 10 of the magnetic resonance apparatus 111 and having a device 1. In this arrangement, the housing element 13 having the device 1 is mounted, as depicted in FIG. 2, on a side part of the front section 10 of the magnetic resonance apparatus 111. The device 1 is thus arranged “laterally” adjacent to the patient receiving zone 114 having the patient positioning device 116, where laterally refers to a direction perpendicular to a weight force acting on the device 1. By virtue of the arrangement on the front section 10, the device 1 is nonetheless visible to an observer of the magnetic resonance apparatus 111 and therefore may exhibit its design effect.

The device 1 has two end sections that are positioned in the force of gravity direction at two opposite ends of the device 1. The end sections are therefore positioned at two opposite ends of the device 1 along the longitudinal extension of the device 1. A first reservoir 7 is arranged in the first end section, which is positioned above the second end section in accordance with the force of gravity direction. A second reservoir 8 is arranged in the second end section. The first reservoir 7 is connected to the second reservoir 8 by way of five channels 2. In this case, the channels 2 are arranged so as to be visible to an observer facing the front section 10 of the magnetic resonance apparatus 111. A light source 9 is also arranged in each end section. The light sources 9 enable the device 1, in particular the channels 2 of the device 1, to be illuminated. In this arrangement, the channels 2 are embodied as light conductors in order to reinforce the illumination effect achieved by the light sources 9.

The housing element 13 has an optically transparent subsection, the device 1 being arranged at least partially on the optically transparent subsection. Thus, the device 1 is arranged at the front side of the housing element 13, viewed from the standpoint of the observer. In this arrangement, the housing element 13 is embodied in such a way that for each channel 2 of the device it has a recess in which the channel 2 is incorporated. The channels 2 are in this case embodied in a curved shape, as depicted in FIG. 2, and comply with a curvature of the housing element 13 and of the front section 10 of the magnetic resonance apparatus 111. With regard to a viewing direction 11 of the observer from the front onto the device 1 and/or the front section 10 of the magnetic resonance apparatus 111, the channels 2 are arranged laterally adjacent to one another perpendicularly to the viewing direction 11. In this case, the radius of curvature of the channels 2 likewise points perpendicularly to the viewing direction 11. The device 1 is in turn embodied as a two-shell structure, the channels 2 being arranged inside the two-shell embodiment. In this arrangement, the device 1 has a first shell having first recesses and a second shell having second recesses, the first recesses corresponding to the second recesses in such a way that the first recesses together with the second recesses form the channels 2 when the first shell is joined to the second shell. In this case, the shell pointing toward the observer of the device 1 is embodied as optically transparent. The viewing direction 11 of the observer in this case points into the drawing plane in FIG. 2.

A first liquid 3 of the device 1 and a second liquid 4 of the device 1 are arranged in the channels 2, the first liquid 3, and the second liquid 4 having different densities and being immiscible. In this case, the first liquid 3 has a higher density than the second liquid 4. At the same time the liquids 3,4 are of different colors. Thus, the first liquid 3 is embodied as colored, (e.g., blue), while the second liquid 4 is colorless. The first liquid 3 includes, for example, water colored by pigment, while the second liquid 4 includes, for example, transparent oil, in particular white oil. In this case, the first liquid 3 forms a first phase and the second liquid 4 a second phase, the first phase and the second phase being present separately from one another. The first liquid 3 and the second liquid 4 also have different polarities.

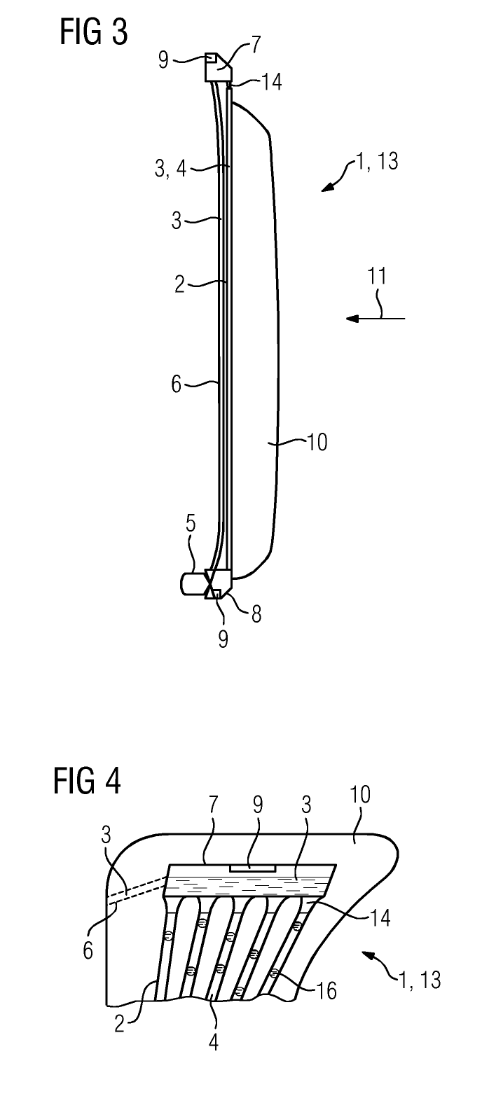

Since each channel 2 has a nozzle 14 at its end facing toward the first reservoir 7 (see FIG. 3 and FIG. 4), the first liquid 3 is introduced, starting from the first reservoir 7, as depicted in FIG. 4, in structures 16 demarcated from the second liquid 4, (e.g., globules and spheres), into each channel 2 filled with the second liquid 4. Because the first liquid 3 has a higher density than the second liquid 4, the first liquid 3 moves downward through the channels 2 along the force of gravity into the second reservoir 8. In this case, the first liquid 3 is conducted in the form of demarcated structures 16 simultaneously through each of the channels 2. As a result of the weight force acting upon them, the demarcated structures 16 of the first liquid 3 execute a movement simultaneously through the channels 2.

The first liquid 3 thereupon collects in the second reservoir 8. From the second reservoir 8, the first liquid 3 is pumped back, as depicted in FIG. 3, by a pump 5 through a feed channel 6 into the first reservoir 7 once again. For an observer facing the front section 10 of the magnetic resonance apparatus 111, the feed channel 6 is in this case arranged behind the channels 2, as a result of which the channels 2 hide the feed channel 6 from an observer. The first liquid 3 collects in the first reservoir 7 until its weight force is great enough for the first liquid 3 to be introduced through the nozzles 14 into the channels 2 once again due to its weight force. This accordingly closes the circuit of the first liquid 3 moving within the transparent second liquid 4. The principle of the movement of the two liquids 3,4 may be compared in this case with a cleanroom principle, in which air collects in a reservoir until such time as, due to its weight force, the air is introduced in a laminar flow through nozzles into the cleanroom.

The device 1 is in this case embodied as magnetic resonance compatible to the extent that the device 1 may include nonmagnetic materials, in particular transparent Plexiglas. Furthermore, the pump 5 of the device for example is positioned such that it is placed at the greatest possible distance from the center of the main magnetic field 118 and as far as possible outside of potential gradient fields that may be generated by the gradient coil unit 119 of the magnetic resonance apparatus 111.

The side view of FIG. 3 depicts a side view of an exemplary channel 2 without taking account of its curvature. In this view, the viewing direction 11 of an observer onto the front covering panel 10 of the magnetic resonance apparatus 111 is indicated by an arrow.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A device comprising:
at least one channel, wherein the at least one channel comprises at least one first liquid having a first density and at least one second liquid having a second density, wherein the first density is different from the second density,
wherein the at least one first liquid and the at least one second liquid are arranged at least partially inside the at least one channel, and
wherein the at least one first liquid comprises a plurality of structures that are demarcated from the at least one second liquid and which, when acted upon by a force, execute a movement inside the at least one channel.

2. The device as claimed in claim 1, wherein the at least one first liquid and the at least one second liquid are of different colors.

3. The device as claimed in claim 1, wherein the at least one first liquid comprises a higher density than the at least one second liquid.

4. The device as claimed in claim 1 further comprising a plurality of channels, the plurality of channels configured such that the demarcated structures of the at least one first liquid, when acted upon by the force, execute a movement simultaneously through each channel of the plurality of channels.

5. The device as claimed in claim 1 further comprising at least one first shell having at least one first recess and a second shell having at least one second recess,
wherein the at least one first recess corresponds to the at least one second recess such that, when the at least one first shell is joined to the at least one second shell, the at least one first recess together with the at least one second recess forms the at least one channel.

6. The device as claimed in claim 1 further comprising at least one nozzle configured to introduce the at least one first liquid in the form of demarcated structures into the at least one channel.

7. The device as claimed in claim 1 further comprising at least one pump configured to set the at least one first liquid in motion.

8. The device as claimed in claim 1 further comprising:
at least one first end section and at least one second end section, wherein the at least one second end section is positioned opposite the at least one first end section; and
at least one first reservoir and at least one second reservoir, wherein the at least one first reservoir is arranged in the at least first end section, and the at least one second reservoir is arranged in the at least one second end section, wherein the first reservoir is connected to the at least one second reservoir by the at least one channel.

9. The device as claimed in claim 8, wherein the at least one pump is configured to pump the at least one first liquid from the at least one second reservoir into the at least one first reservoir.

10. The device as claimed in claim 8 further comprising at least one feed channel configured differently from the at least one channel, wherein the at least one first reservoir is connected to the at least one second reservoir by the at least one feed channel.

11. The device as claimed in claim 7, wherein the at least one pump is configured to pump the at least one first liquid from the at least one second reservoir into the at least one first reservoir.

12. The device as claimed in claim 11 further comprising at least one feed channel configured differently from the at least one channel, wherein the at least one first reservoir is connected to the at least one second reservoir by the at least one feed channel.

13. The device as claimed in claim 1 further comprising at least one light source, wherein the at least one light source is configured to illuminate the at least one channel.

14. The device as claimed in claim 13, wherein the at least one channel is a light conductor for the light generated by the at least one light source.

15. The device as claimed in claim 1, wherein the device is magnetic resonance compatible.

16. A housing element comprising:
a device comprising:
at least one channel, wherein the at least one channel comprises at least one first liquid having a first density and at least one second liquid having a second density, wherein the first density is different from the second density,
wherein the at least one first liquid and the at least one second liquid are arranged at least partially inside the at least one channel, and
wherein the at least one first liquid comprises a plurality of structures that are demarcated from the at least one second liquid and which, when acted upon by a force, execute a movement inside the at least one channel.
wherein the device is curved, and
wherein the curvature of the device is matched to a curvature of the shape of the housing element.

17. The housing element as claimed in claim 16, wherein the housing element has an optically transparent subsection, wherein the device is arranged at least partially on the optically transparent subsection.

18. A medical imaging apparatus comprising:
a front section of the medical imaging apparatus; and
a housing element comprising a device arranged on the front section of the medical imaging apparatus, the device comprising:
at least one channel, wherein the at least one channel comprises at least one first liquid having a first density and at least one second liquid having a second density, wherein the first density is different from the second density,
wherein the at least one first liquid and the at least one second liquid are arranged at least partially inside the at least one channel, and
wherein the at least one first liquid comprises a plurality of structures that are demarcated from the at least one second liquid and which, when acted upon by a force, execute a movement inside the at least one channel.

19. The medical imaging apparatus as claimed in claim 18, wherein the device is curved, and wherein the curvature of the device is matched to a curvature of the shape of the housing element.

20. The medical imaging apparatus as claimed in claim 19, wherein the housing element has an optically transparent subsection, wherein the device is arranged at least partially on the optically transparent subsection.
